(19) United States
(12) Patent Application Publication
(10) Pub. No.: US 2025/0343120 A1
(43) Pub. Date: Nov. 6, 2025

(54) FABRICATION METHOD FOR LEAD FRAME PACKAGED DEVICE

(71) Applicant: Infineon Technologies Austria AG, Villach (AT)

(72) Inventors: Yong Jin KANG, Cheonan-si (KR); Hyeon Min JEONG, Gwangju (KR); Kyoung Min SONG, Cheonan-si (KR); Jae Hoon KANG, Cheonan-si (KR); Kil Su LEE, Kwang Ju (KR)

(21) Appl. No.: 18/652,646

(22) Filed: May 1, 2024

(51) Int. Cl. H01L 23/495; H01L 23/00

(52) U.S. Cl. CPC H01L 23/49582; H01L 24/03; H01L 24/43; H01L 2224/0346; H01L 2224/43825; H01L 2924/1815

(57) ABSTRACT

A method of fabricating a lead frame packaged device includes providing a lead frame including at least one wire bond area and a plurality of leads extending from the at least one wire bond area, wherein each wire bond area includes a plurality of bond pads; depositing a nickel plating on each wire bond area to form nickel-plated bond pads; depositing a plating masking material on the nickel plating to form a masking layer on the nickel plating; depositing a tin plating on the lead frame, including on the plurality of leads, wherein the plating masking material prevents the tin plating from making contact with the nickel plating; removing the masking layer from the lead frame to expose the nickel plating on each wire bond area; attaching a die to the lead frame; and forming wire bonds between the die and the nickel-plated bond pads.

### BACKGROUND

Lead frames are metal components used in semiconductor packaging to provide electrical and mechanical connections between a die (e.g., a chip) and an external device. Lead frames typically include a central area in which the die is arranged, and leads (e.g., metal conductors) that surround the central area and lead away from the die. Small bond wires may connect the die to each lead. Some lead frames include a central metal part, or die pad, in the central area used to support the die, and leads or pins that extend from the die pad to an external area of the package. Lead frames are often made of a combination of materials such as copper or copper alloys, and are used in various packaging technologies. Lead frames are typically manufactured through stamping, electroplating, and/or etching processes, and are critical components for ensuring high-yield, reliable, and cost-effective packaging solutions for semiconductor dies. Etching may be used in lead frame production to create precise and accurate patterns on the metal sheets used for lead frames. The etching process removes unwanted metal to form the desired lead frame shape. The lead frame is then used to support and electrically connect the die in semiconductor packaging. The etching process can be performed using either dry or wet etching techniques. Stamping may be used in lead frame production to produce high volumes of lead frames with precise and consistent dimensions. The stamping process involves using a tool and die set and a stamping press to punch and form the lead frame material into the desired shape. Stamping is an efficient and cost-effective method of producing lead frames for use in electronic components and devices.

### SUMMARY

In some implementations, a method of fabricating a lead frame packaged device includes providing a lead frame comprising at least one wire bond area and a plurality of leads extending from the at least one wire bond area, wherein each wire bond area includes a plurality of bond pads; depositing a nickel plating on each wire bond area to form nickel-plated bond pads; depositing a plating masking material on the nickel plating to form a masking layer on the nickel plating; depositing a tin plating on the lead frame, including on the plurality of leads; removing the masking layer from the lead frame to expose the nickel plating on each wire bond area; attaching a die to the lead frame; forming wire bonds between the die and the nickel-plated bond pads; and forming a package casing over the die, the wire bonds, and the nickel-plated bond pads.

In some implementations, a method of fabricating a lead frame packaged device includes providing a lead frame comprising a plurality of leads, wherein the lead frame includes a plating area that includes the plurality of leads, and wherein the lead frame includes a non-plating area; depositing a bonding layer on the non-plating area to form a plated area; depositing a plating masking material on the plated area to form a masking layer on the bonding layer; depositing a release layer on the plating area of the lead frame, including on the plurality of leads, wherein the plating masking material prevents the release layer from making contact with the plated area; removing the masking layer from the lead frame to expose the bonding layer in the non-plating area; attaching a die to the lead frame; forming wire bonds between the die and the nickel-plated area; and forming a package casing over the die, the wire bonds, and the nickel-plated area.

In some implementations, a method of fabricating a plurality of lead frame packaged devices includes providing a lead frame array comprising a plurality of lead frames coupled together, wherein each lead frame includes at least one a wire bond area and a plurality of leads extending from the at least one wire bond area; depositing a nickel plating on each wire bond area to form nickel-plated bond pads, wherein each lead frame is associated with a respective group of nickel-plated bond pads; depositing a plating masking material on the nickel plating to form a masking layer on the nickel plating; depositing a tin plating on the lead frame array, including on each of the plurality of leads, wherein the plating masking material prevents the tin plating from making contact with the nickel plating; removing the masking layer from the lead frame array to expose the nickel plating on each wire bond area; attaching a plurality of dies to the lead frame array, wherein each die is attached to a respective lead frame of the lead frame array; for each die, forming wire bonds between a die and the respective group of nickel-plated bond pads associated with the respective lead frame attached to the die; for each respective lead frame, forming a separate package casing over the die, the wire bonds, and the respective group of nickel-plated bond pads associated with the respective lead frame; and subsequent to forming the separate package casing for each respective lead frame, separating the plurality of lead frames to form the plurality of lead frame packaged devices.

In some implementations, a method of fabricating a lead frame packaged device includes providing a lead frame comprising at least one wire bond area and a plurality of leads extending from the at least one wire bond area, wherein each wire bond area includes a plurality of bond pads; depositing a bonding layer on each wire bond area to form plated bond pads; depositing a plating masking material on the nickel plating to form a masking layer on the bonding layer; depositing a release layer on the lead frame, including on the plurality of leads; removing the masking layer from the lead frame to expose the bonding layer on each wire bond area; attaching a die to the lead frame; forming wire bonds between the die and the plated bond pads; and forming a package casing over the die, the wire bonds, and the nickel-plated bond pads.

### BRIEF DESCRIPTION OF THE DRAWINGS

Implementations are described herein making reference to the appended drawings.

FIGS. 1A-1G show a method of fabricating a plurality of lead frame packaged devices according to one or more implementations.

FIG. 2 shows a lead frame packaged device.

FIG. 3 is a flowchart of an example process associated with fabrication method for lead frame packaged device.

FIG. 4 is a flowchart of an example process associated with fabrication method for lead frame packaged device.

### DETAILED DESCRIPTION

In the following, details are set forth to provide a more thorough explanation of example implementations. However, it will be apparent to those skilled in the art that these implementations may be practiced without these specific details. In other instances, well-known structures and devices are shown in block diagram form or in a schematic view rather than in detail in order to avoid obscuring the implementations. In addition, features of the different implementations described hereinafter may be combined with each other, unless specifically noted otherwise.

Further, equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually exchangeable.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In implementations described herein or shown in the drawings, any direct electrical connection or coupling, e.g., any connection or coupling without additional intervening elements, may also be implemented by an indirect connection or coupling, e.g., a connection or coupling with one or more additional intervening elements, or vice versa, as long as the general purpose of the connection or coupling, for example, to transmit a certain kind of signal or to transmit a certain kind of information, is essentially maintained. Features from different implementations may be combined to form further implementations. For example, variations or modifications described with respect to one of the implementations may also be applicable to other implementations unless noted to the contrary.

In the present disclosure, expressions including ordinal numbers, such as “first”, “second”, and/or the like, may modify various elements. However, such elements are not limited by the above expressions. For example, the above expressions do not limit the sequence and/or importance of the elements. The above expressions are used merely for the purpose of distinguishing an element from the other elements. For example, a first box and a second box indicate different boxes, although both are boxes. For further example, a first element could be termed a second element, and similarly, a second element could also be termed a first element without departing from the scope of the present disclosure.

A lead frame package typically includes a lead frame, made of copper (Cu), aluminum (Al), iron (Fe), molybdenum (Mo), nickel (Ni), chromium (Cr), and/or an alloy thereof, and a package molding formed by a molding process that encapsulates a portion of the lead frame, while permitting portions of the leads of the lead frame to extend outside of the package molding for contact with an external device. Copper (Cu) is susceptible to corrosion that may affect a reliability of the leads. For example, leads of the lead frame that extend out from the package molding may be exposed to air and may oxidize, which may affect an electrical performance (e.g., conductivity) of the leads. Moreover, solder may not bond appropriately with oxidized copper. As a result, poor solder connections with the leads or solder breaks may form as a result of oxidized copper.

Exposed portions of the leads may be plated with tin (Sn) after the molding process of the package molding in order to protect exposed copper from oxidation. However, it may be difficult to ensure that the exposed portions of the leads are fully plated by tin, resulting in non-plates areas that are vulnerable to oxidation. For example, depending on a shape of the package molding and/or the shape of the leads, it may be difficult to ensure that the exposed portions of the leads are fully plated by tin.

A balcony shape molded module is one type of lead frame package that, due to the shape of the package molding and/or the shape of the leads, it is difficult to ensure that the exposed portions of the leads are fully plated by tin. For example, exposed areas of the leads that are close to the package molding may be difficult to plate. As a result, balcony shape molded modules, and other types of lead frame packages, may be vulnerable to reliability issues and electrical performance issues caused by oxidation of the exposed leads. Moreover, it may be difficult to reliably mass produce balcony shape molded modules with high-volume manufacturing due to a risk of leads having non-plated areas. Thus, manufacturing becomes more expensive to ensure exposed areas of the leads are fully plated.

Some implementations are related to plating leads of a lead frame prior to a package molding process used for forming a package casing (e.g., a package molding). However, care should be taken not to plate any wire bond area of the lead frame with tin to ensure reliable wire bond connections. A method of fabricating a lead frame packaged device may include providing a lead frame comprising at least one wire bond area and a plurality of leads extending from the at least one wire bond area, wherein each wire bond area includes a plurality of bond pads; depositing a nickel plating on each wire bond area to form nickel-plated bond pads; depositing a plating masking material on the nickel plating to form a masking layer on the nickel plating; depositing a tin plating on the lead frame, including on the plurality of leads, wherein the plating masking material prevents the tin plating from making contact with the nickel plating; removing the masking layer from the lead frame to expose the nickel plating on each wire bond area; attaching a die to the lead frame; forming wire bonds between the die and the nickel-plated bond pads; and forming a package casing over the die, the wire bonds, and the nickel-plated bond pads. As a result, exposed areas of the leads are fully plated by the tin plating, which may improve a reliability performance and/or an electrical performance of the lead frame packaged device. In addition, the method may enable the lead frame packaged device to be reliably mass produced with high-volume manufacturing with reduced risk that the exposed areas of the leads will have non-plated areas. As a result, the lead frame packaged device may be produced more quickly and at a lower manufacturing cost.

In some implementations, the lead frame packaged device may be a balcony shape molded module. The balcony shape molded module may be an intelligent power module (IPM) that includes at least one integrated power stage that contains a gate driver packaged with both high-side and low-side transistors. Large currents can be conducted through the high-side and low-side transistors. These active components may generate heat while conducting the currents. Thus, it may be important to maintain optimal electrical performance of the leads and solder connections to the leads by preventing oxidation.

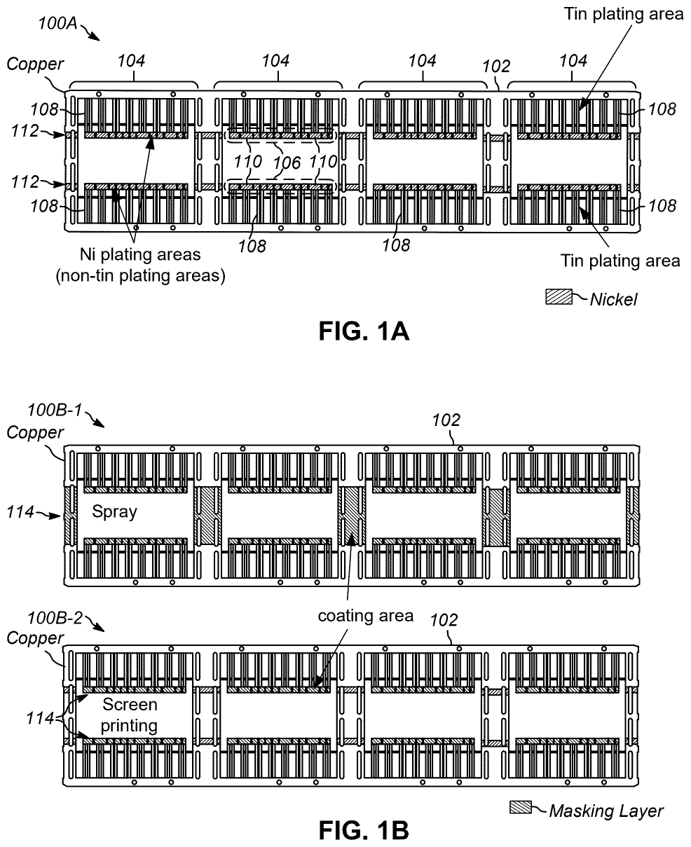

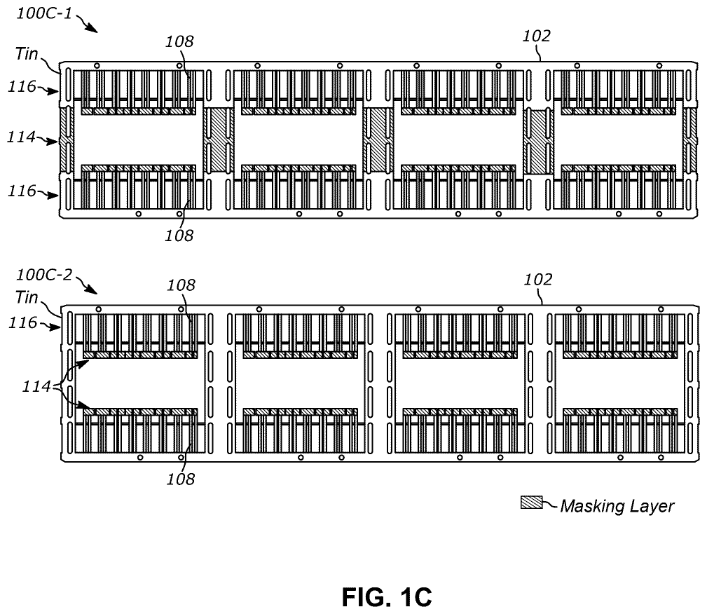

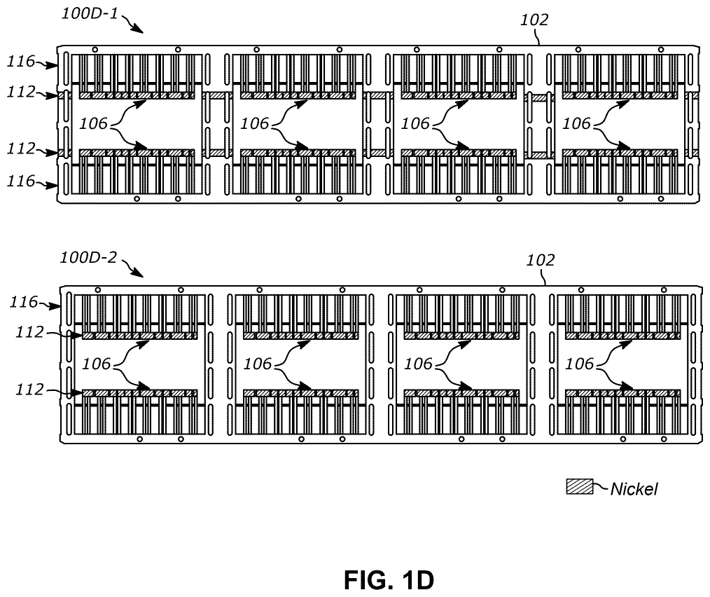

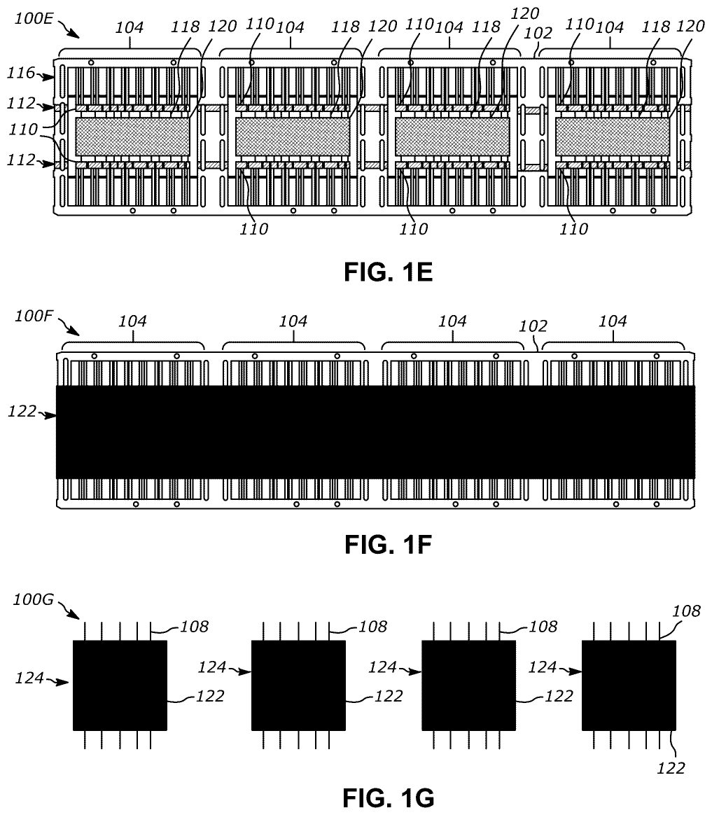

FIGS. 1A-1G show a method of fabricating a plurality of lead frame packaged devices according to one or more implementations.

FIG. 1A shows processing steps 100A that include providing a lead frame array 102. The lead frame array 102 may be made of copper. The lead frame array 102 may include a plurality of lead frames 104 coupled together by a lead frame array structure. Each lead frame 104 includes at least one a wire bond area 106 (e.g., nickel (Ni) plating area) and a plurality of leads 108 extending from the at least one wire bond area 106. Each wire bond area 106 may include a plurality of bond pads 110. Additionally, the lead frame array 102 may include a tin plating area that includes the plurality of leads 108, and a non-tin plating area that includes the wire bond areas 106. Thus, each lead frame 104 may include one or more tin plating areas and one or more non-tin plating areas.

The processing steps 100A also include depositing a nickel plating 112 on each wire bond area 106 to form nickel-plated bond pads (e.g., bond pads 110 with nickel plating). Portions of the plurality of leads 108 outside of the nickel plating area may remain free of the nickel plating 112. Thus, each lead frame 104 may be associated with a respective group of nickel-plated bond pads. The nickel plating 112 may be referred to as a bonding layer. In some implementations, the bonding layer may be made of another material, such as silver (Ag) bonding layer, μPPF (e.g., an Ni/Pd/Au—Ag alloy), or bare copper, instead of nickel.

FIG. 1B shows alternative processing steps 100B-1 and 100B-2 that include depositing a plating masking material on the nickel plating (e.g., on the nickel-plated bond pads in the wire bond areas 106) to form a masking layer 114 on the nickel plating that is made of the plating masking material. Thus, the plating masking material is applied to a coating area. Portions of the plurality of leads 108 outside of the coating area remain free of the plating masking material. The plating masking material may be an organic solderability preservative (OSP), a photoresist material, a light sensitive material, a thermal resistance material, or a chemical resistance material.

In processing step 100B-1, the plating masking material may be applied by spraying the plating masking material onto the wire bond areas 106 to form the masking layer 114. Alternatively, in processing step 100B-2, the plating masking material may be applied by screen printing the plating masking material onto the wire bond areas 106 to form the masking layer 114. In some implementations, the plating masking material may be a film (e.g., a thermal resistance film or a chemical resistance film) that is attached to a selective area that includes the wire bond areas 106 using a film attach process. In each case, the masking layer 114 is formed on the lead frame array 102 over the nickel-plated bond pads to protect or otherwise shield the nickel-plated bond pads.

FIG. 1C shows alternative processing steps 100C-1 and 100C-2 that include depositing a tin plating 116 on the lead frame array 102, including on each of the plurality of leads 108. Processing step 100C-1 may correspond to a process flow corresponding to processing step 100B-1. Processing step 100C-2 may correspond to a process flow corresponding to processing step 100B-2. The tin plating 116 may be referred to as a release layer. In some implementations, the release layer may be made of another material, such as wax, polyimide film, silicone, release spray, instead of tin.

The plating masking material of the masking layer 114 prevents the tin plating 116 from making contact with the nickel plating (e.g., with the nickel-plated bond pads in the wire bond areas 106). Thus, the exposed copper portions of the lead frame array 102, including the leads 108, are fully plated (e.g., coated) by the tin plating 116. In some implementations, electroplating may be used to deposit the tin plating 116 onto the exposed copper portions of the lead frame array 102. Some of the tin plating 116 may be deposited on the masking layer 114, but not directly onto the nickel-plated bond pads. Thus, depositing the tin plating 116 on the lead frame array 102 may include completely coating each of the plurality of leads 108 with tin.

FIG. 1D shows alternative processing steps 100D-1 and 100D-2 that include removing the masking layer 114 from the lead frame array 102 to expose the nickel plating 112 on each wire bond area 106. In other words, the masking layer 114 is removed to expose the nickel-plated bond pads in the wire bond areas 106. Removing the masking layer 114 may include removing any tin of the tin plating 116 that was deposited on the masking layer 114 from the lead frame array 102.

Processing step 100D-1 may correspond to a process flow corresponding to processing steps 100B-1 and 100C-1. Processing step 100D-2 may correspond to a process flow corresponding to processing steps 100B-2 and 100C-2.

FIG. 1E shows processing steps 100E that include attaching a plurality of dies 118 to the lead frame array 102 and forming wire bonds 120. Each die 118 may be attached to a respective lead frame 104 of the lead frame array 102. In addition, forming the wire bonds 120 may include, for each die 118, forming wire bonds between the die 118 and the respective group of nickel-plated bond pads (e.g., bond pads 110) associated with the respective lead frame 104 attached to the die 118.

FIG. 1F shows a processing step 100F that includes, for each respective lead frame 104, forming a separate package casing 122 over the die 118, the wire bonds 120, and the respective group of nickel-plated bond pads (e.g., bond pads 110) associated with the respective lead frame 104. The nickel deposited on the bond pads 110 improves wire bonding connections to the bond pads 110. The separate package casings 122 may be initially formed as a single structure and then formed into discrete structures, or may be formed initially as discrete structures. The separate package casings 122 may be package moldings made of a molding material that is deposited and subsequently cured. Thus, the tin plating 116 is formed on all exposed copper portions of the lead frame array 102 prior to forming the package casings 122, ensuring that there are no non-plated copper portions that could be oxidized due to unwanted exposure to air. The shape of the separate package casings is no longer a factor that impedes the tin plating processes for full tin plating coverage.

FIG. 1G shows a processing step 100G that includes, subsequent to forming the separate package casing 122 for each respective lead frame 104, separating the plurality of lead frames 104 to form a plurality of lead frame packaged devices 124. The plurality of lead frames 104 may be separated by sawing, cutting, or any other separation technique.

As indicated above, FIGS. 1A-1G are provided merely as examples. Other examples are possible and may differ from what was described with regard to FIGS. 1A-1G. In some implementations, processing steps 100A-100G may include additional steps, fewer steps, different steps, or differently arranged steps than those depicted in FIGS. 1A-1G.

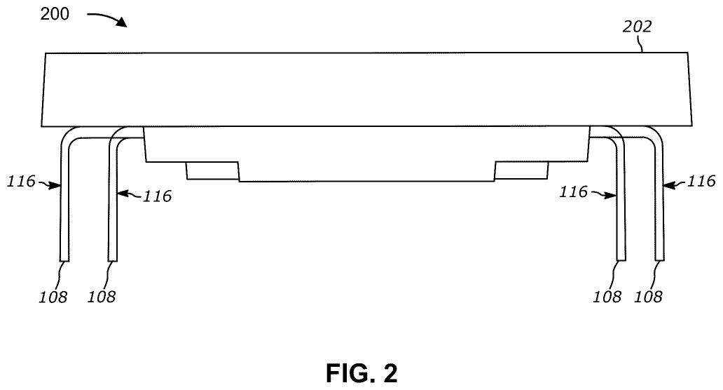

FIG. 2 shows a lead frame packaged device 200. The lead frame packaged device 200 may be made using processing steps 100A-100G described in connection with FIGS. 1A-1G. The lead frame packaged device 200 includes a balcony shape molded package casing 202 and a plurality of leads 108 that are fully plated with tin plating 116 (e.g., a plurality of tin-plated leads). Areas of the leads 108 close the balcony shape molded package casing 202 are plated with tin, which may not be the case if the leads 108 were to be plated after forming the balcony shape molded package casing 202 due to obstruction by the balcony shape molded package casing 202.

As a result, exposed areas of the leads 108 are fully plated by the tin plating 116 during the method described in connection with FIGS. 1A-1G, which may improve a reliability performance and/or an electrical performance of the lead frame packaged device 200. In addition, the method described in connection with FIGS. 1A-1G may enable the lead frame packaged device 200 to be reliably mass produced with high-volume manufacturing with reduced risk that the exposed areas of the leads will have non-plated areas. As a result, the lead frame packaged device 200 may be produced more quickly and at a lower manufacturing cost.

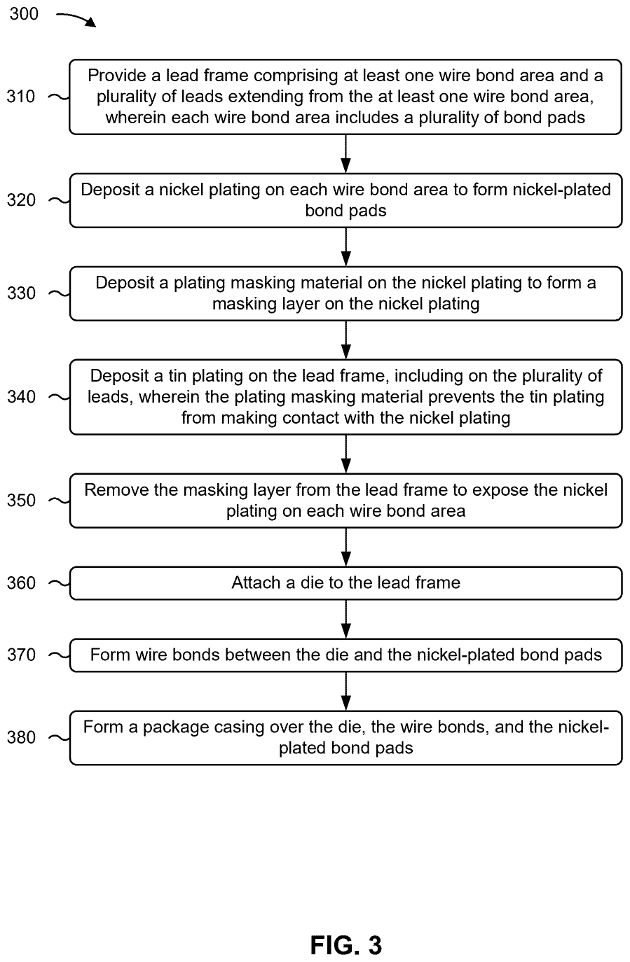

FIG. 3 is a flowchart of an example process 300 associated with fabrication method for lead frame packaged device. As shown in FIG. 3, process 300 may include providing a lead frame comprising at least one wire bond area and a plurality of leads extending from the at least one wire bond area, wherein each wire bond area includes a plurality of bond pads (block 310).

As further shown in FIG. 3, process 300 may include depositing a nickel plating on each wire bond area to form nickel-plated bond pads (block 320).

As further shown in FIG. 3, process 300 may include depositing a plating masking material on the nickel plating to form a masking layer on the nickel plating (block 330).

As further shown in FIG. 3, process 300 may include depositing a tin plating on the lead frame, including on the plurality of leads, wherein the plating masking material prevents the tin plating from making contact with the nickel plating (block 340).

As further shown in FIG. 3, process 300 may include removing the masking layer from the lead frame to expose the nickel plating on each wire bond area (block 350).

As further shown in FIG. 3, process 300 may include attaching a die to the lead frame (block 360).

As further shown in FIG. 3, process 300 may include forming wire bonds between the die and the nickel-plated bond pads (block 370).

As further shown in FIG. 3, process 300 may include forming a package casing over the die, the wire bonds, and the nickel-plated bond pads (block 380).

Process 300 may include additional implementations, such as any single implementation or any combination of implementations described below and/or in connection with one or more other processes described elsewhere herein.

In a first implementation, depositing the tin plating on the lead frame includes completely coating each of the plurality of leads with tin.

In a second implementation, the plating masking material is an OSP.

In a third implementation, the lead frame is a copper lead frame.

In a fourth implementation, the plating masking material is a photoresist material, a thermal resistance material, or a chemical resistance material.

In a fifth implementation, depositing the tin plating on the lead frame includes partially coating the masking layer with tin.

In a sixth implementation, the package casing is balcony-shaped molded casing.

In a seventh implementation, attaching the die to the lead frame is performed subsequent to removing the masking layer from the lead frame.

In an eighth implementation, removing the masking layer includes removing any tin of the tin plating deposited on the masking layer from the lead frame.

Although FIG. 3 shows example blocks of process 300, in some implementations, process 300 includes additional blocks, fewer blocks, different blocks, or differently arranged blocks than those depicted in FIG. 3. Additionally, or alternatively, two or more of the blocks of process 300 may be performed in parallel.

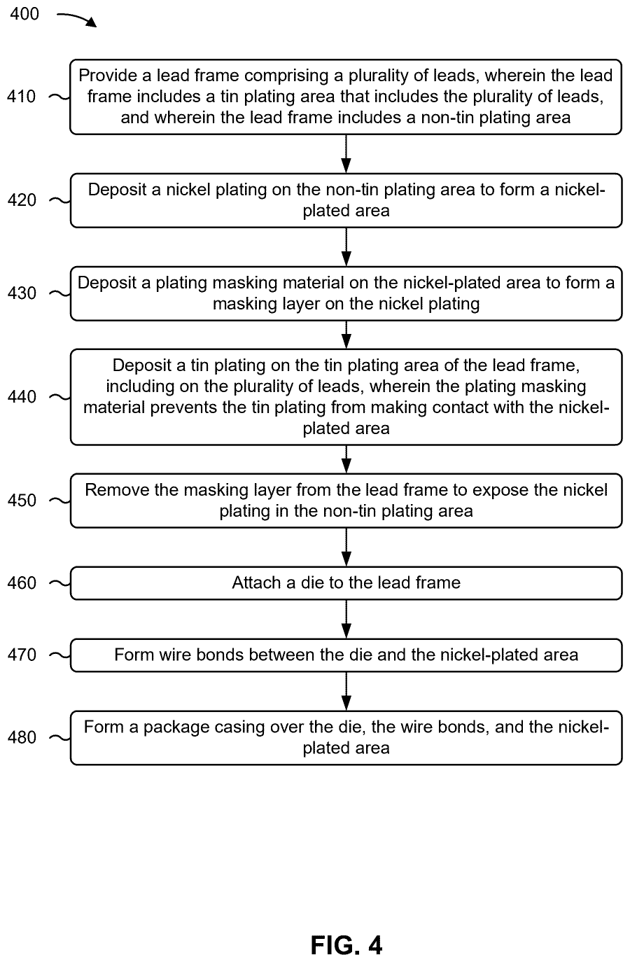

FIG. 4 is a flowchart of an example process 400 associated with fabrication method for lead frame packaged device. As shown in FIG. 4, process 400 may include providing a lead frame comprising a plurality of leads, wherein the lead frame includes a tin plating area that includes the plurality of leads, and wherein the lead frame includes a non-tin plating area (block 410).

As further shown in FIG. 4, process 400 may include depositing a nickel plating on the non-tin plating area to form a nickel-plated area (block 420).

As further shown in FIG. 4, process 400 may include depositing a plating masking material on the nickel-plated area to form a masking layer on the nickel plating (block 430).

As further shown in FIG. 4, process 400 may include depositing a tin plating on the tin plating area of the lead frame, including on the plurality of leads, wherein the plating masking material prevents the tin plating from making contact with the nickel-plated area (block 440).

As further shown in FIG. 4, process 400 may include removing the masking layer from the lead frame to expose the nickel plating in the non-tin plating area (block 450).

As further shown in FIG. 4, process 400 may include attaching a die to the lead frame (block 460).

As further shown in FIG. 4, process 400 may include forming wire bonds between the die and the nickel-plated area (block 470).

As further shown in FIG. 4, process 400 may include forming a package casing over the die, the wire bonds, and the nickel-plated area (block 480).

Process 400 may include additional implementations, such as any single implementation or any combination of implementations described below and/or in connection with one or more other processes described elsewhere herein.

In a first implementation, the non-tin plating area includes at least one wire bond area to which the nickel plating is applied.

In a second implementation, depositing the tin plating on the lead frame includes completely coating each of the plurality of leads with tin.

In a third implementation, the plating masking material is an OSP, a photoresist material, a thermal resistance material, or a chemical resistance material.

In a fourth implementation, the lead frame is a copper lead frame.

In a fifth implementation, depositing the tin plating on the lead frame includes at least partially coating the masking layer with tin.

In a sixth implementation, removing the masking layer includes removing any tin of the tin plating deposited on the masking layer from the lead frame.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

The following provides an overview of some Aspects of the present disclosure:
Aspect 1: A method of fabricating a lead frame packaged device, the method comprising: providing a lead frame comprising at least one wire bond area and a plurality of leads extending from the at least one wire bond area, wherein each wire bond area includes a plurality of bond pads; depositing a nickel plating on each wire bond area to form nickel-plated bond pads; depositing a plating masking material on the nickel plating to form a masking layer on the nickel plating; depositing a tin plating on the lead frame, including on the plurality of leads; removing the masking layer from the lead frame to expose the nickel plating on each wire bond area; attaching a die to the lead frame; forming wire bonds between the die and the nickel-plated bond pads; and forming a package casing over the die, the wire bonds, and the nickel-plated bond pads.
Aspect 2: The method of Aspect 1, wherein depositing the tin plating on the lead frame includes completely coating each of the plurality of leads with tin.
Aspect 3: The method of any of Aspects 1-2, wherein the plating masking material is an organic solderability preservative (OSP).
Aspect 4: The method of Aspect 3, wherein the lead frame is a copper lead frame.
Aspect 5: The method of any of Aspects 1-4, wherein the plating masking material is a photoresist material, a thermal resistance material, or a chemical resistance material.
Aspect 6: The method of any of Aspects 1-5, wherein depositing the tin plating on the lead frame includes partially coating the masking layer with tin.
Aspect 7: The method of any of Aspects 1-6, wherein the package casing is balcony-shaped molded casing.
Aspect 8: The method of any of Aspects 1-7, wherein attaching the die to the lead frame is performed subsequent to removing the masking layer from the lead frame.
Aspect 9: The method of any of Aspects 1-8, wherein removing the masking layer includes removing any tin of the tin plating deposited on the masking layer from the lead frame.
Aspect 10: The method of any of Aspects 1-9, wherein the plating masking material prevents the tin plating from making contact with the nickel plating.
Aspect 11: A method of fabricating a lead frame packaged device, the method comprising: providing a lead frame comprising a plurality of leads, wherein the lead frame includes a plating area that includes the plurality of leads, and wherein the lead frame includes a non-plating area; depositing a bonding layer on the non-plating area to form a plated area; depositing a plating masking material on the plated area to form a masking layer on the bonding layer; depositing a release layer on the plating area of the lead frame, including on the plurality of leads, wherein the plating masking material prevents the release layer from making contact with the plated area; removing the masking layer from the lead frame to expose the bonding layer in the non-plating area; attaching a die to the lead frame; forming wire bonds between the die and the nickel-plated area; and forming a package casing over the die, the wire bonds, and the nickel-plated area.
Aspect 12: The method of Aspect 10, wherein the non-plating area includes at least one wire bond area to which the bonding layer is applied.
Aspect 13: The method of Aspect 10, wherein depositing the release layer on the lead frame includes completely coating each of the plurality of leads with the release layer.
Aspect 14: The method of Aspect 10, wherein the plating masking material is an organic solderability preservative (OSP), a photoresist material, a thermal resistance material, or a chemical resistance material.
Aspect 15: The method of Aspect 10, wherein depositing the release layer on the lead frame includes at least partially coating the masking layer with the release layer.
Aspect 16: The method of Aspect 15, wherein removing the masking layer includes removing any release material of the release layer deposited on the masking layer from the lead frame.
Aspect 17: A method of fabricating a plurality of lead frame packaged devices, the method comprising: providing a lead frame array comprising a plurality of lead frames coupled together, wherein each lead frame includes at least one a wire bond area and a plurality of leads extending from the at least one wire bond area; depositing a nickel plating on each wire bond area to form nickel-plated bond pads, wherein each lead frame is associated with a respective group of nickel-plated bond pads; depositing a plating masking material on the nickel plating to form a masking layer on the nickel plating; depositing a tin plating on the lead frame array, including on each of the plurality of leads, wherein the plating masking material prevents the tin plating from making contact with the nickel plating; removing the masking layer from the lead frame array to expose the nickel plating on each wire bond area; attaching a plurality of dies to the lead frame array, wherein each die is attached to a respective lead frame of the lead frame array; for each die, forming wire bonds between a die and the respective group of nickel-plated bond pads associated with the respective lead frame attached to the die; for each respective lead frame, forming a separate package casing over the die, the wire bonds, and the respective group of nickel-plated bond pads associated with the respective lead frame; and subsequent to forming the separate package casing for each respective lead frame, separating the plurality of lead frames to form the plurality of lead frame packaged devices.
Aspect 18: The method of Aspect 17, wherein depositing the tin plating on the lead frame array includes completely coating each of the plurality of leads with tin.
Aspect 19: The method of any of Aspects 17-18, wherein the plating masking material is an organic solderability preservative (OSP), a photoresist material, a thermal resistance material, or a chemical resistance material.
Aspect 20: A method of fabricating a lead frame packaged device, the method comprising: providing a lead frame comprising at least one wire bond area and a plurality of leads extending from the at least one wire bond area, wherein each wire bond area includes a plurality of bond pads; depositing a bonding layer on each wire bond area to form plated bond pads; depositing a plating masking material on the nickel plating to form a masking layer on the bonding layer; depositing a release layer on the lead frame, including on the plurality of leads; removing the masking layer from the lead frame to expose the bonding layer on each wire bond area; attaching a die to the lead frame; forming wire bonds between the die and the plated bond pads; and forming a package casing over the die, the wire bonds, and the nickel-plated bond pads.
Aspect 21: A system configured to perform one or more operations recited in one or more of Aspects 1-20.
Aspect 22: An apparatus comprising means for performing one or more operations recited in one or more of Aspects 1-20.
Aspect 23: A non-transitory computer-readable medium storing a set of instructions, the set of instructions comprising one or more instructions that, when executed by a device, cause the device to perform one or more operations recited in one or more of Aspects 1-20.
Aspect 24: A computer program product comprising instructions or code for executing one or more operations recited in one or more of Aspects 1-20.

The foregoing disclosure provides illustration and description but is not intended to be exhaustive or to limit the implementations to the precise forms disclosed. Modifications and variations may be made in light of the above disclosure or may be acquired from practice of the implementations described herein.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “top,” “bottom,” “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” For example, the terms “substantially” and “approximately” may be used herein to account for small manufacturing tolerances or other factors (e.g., within 5%) that are deemed acceptable in the industry without departing from the aspects of the implementations described herein. For example, a resistor with an approximate resistance value may practically have a resistance within 5% of the approximate resistance value. As another example, an approximate signal value may practically have a signal value within 5% of the approximate signal value.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

Further, it is to be understood that the disclosure of multiple acts or functions disclosed in the specification or in the claims may not be construed as to be within the specific order. Therefore, the disclosure of multiple acts or functions will not limit these to a particular order unless such acts or functions are not interchangeable for technical reasons. Furthermore, in some implementations, a single act may include or may be broken into multiple sub acts. Such sub acts may be included and part of the disclosure of this single act unless explicitly excluded.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method of fabricating a lead frame packaged device, the method comprising:
providing a lead frame comprising at least one wire bond area and a plurality of leads extending from the at least one wire bond area, wherein each wire bond area includes a plurality of bond pads;
depositing a nickel plating on each wire bond area to form nickel-plated bond pads;
depositing a plating masking material on the nickel plating to form a masking layer on the nickel plating;
depositing a tin plating on the lead frame, including on the plurality of leads;
removing the masking layer from the lead frame to expose the nickel plating on each wire bond area;
attaching a die to the lead frame;
forming wire bonds between the die and the nickel-plated bond pads; and
forming a package casing over the die, the wire bonds, and the nickel-plated bond pads.

2. The method of claim 1, wherein depositing the tin plating on the lead frame includes completely coating each of the plurality of leads with tin.

3. The method of claim 1, wherein the plating masking material is an organic solderability preservative (OSP).

4. The method of claim 3, wherein the lead frame is a copper lead frame.

5. The method of claim 1, wherein the plating masking material is a photoresist material, a thermal resistance material, or a chemical resistance material.

6. The method of claim 1, wherein depositing the tin plating on the lead frame includes partially coating the masking layer with tin.

7. The method of claim 1, wherein the package casing is balcony-shaped molded casing.

8. The method of claim 1, wherein attaching the die to the lead frame is performed subsequent to removing the masking layer from the lead frame.

9. The method of claim 1, wherein removing the masking layer includes removing any tin of the tin plating deposited on the masking layer from the lead frame.

10. The method of claim 1, wherein the plating masking material prevents the tin plating from making contact with the nickel plating.

11. A method of fabricating a lead frame packaged device, the method comprising:
providing a lead frame comprising a plurality of leads, wherein the lead frame includes a plating area that includes the plurality of leads, and wherein the lead frame includes a non-plating area;
depositing a bonding layer on the non-plating area to form a plated area;
depositing a plating masking material on the plated area to form a masking layer on the bonding layer;
depositing a release layer on the plating area of the lead frame, including on the plurality of leads, wherein the plating masking material prevents the release layer from making contact with the plated area;
removing the masking layer from the lead frame to expose the bonding layer in the non-plating area;
attaching a die to the lead frame;
forming wire bonds between the die and the nickel-plated area; and
forming a package casing over the die, the wire bonds, and the nickel-plated area.

12. The method of claim 10, wherein the non-plating area includes at least one wire bond area to which the bonding layer is applied.

13. The method of claim 10, wherein depositing the release layer on the lead frame includes completely coating each of the plurality of leads with the release layer.

14. The method of claim 10, wherein the plating masking material is an organic solderability preservative (OSP), a photoresist material, a thermal resistance material, or a chemical resistance material.

15. The method of claim 10, wherein depositing the release layer on the lead frame includes at least partially coating the masking layer with the release layer.

16. The method of claim 15, wherein removing the masking layer includes removing any release material of the release layer deposited on the masking layer from the lead frame.

17. A method of fabricating a plurality of lead frame packaged devices, the method comprising:
providing a lead frame array comprising a plurality of lead frames coupled together, wherein each lead frame includes at least one a wire bond area and a plurality of leads extending from the at least one wire bond area;
depositing a nickel plating on each wire bond area to form nickel-plated bond pads, wherein each lead frame is associated with a respective group of nickel-plated bond pads;
depositing a plating masking material on the nickel plating to form a masking layer on the nickel plating;
depositing a tin plating on the lead frame array, including on each of the plurality of leads, wherein the plating masking material prevents the tin plating from making contact with the nickel plating;
removing the masking layer from the lead frame array to expose the nickel plating on each wire bond area;
attaching a plurality of dies to the lead frame array, wherein each die is attached to a respective lead frame of the lead frame array;
for each die, forming wire bonds between a die and the respective group of nickel-plated bond pads associated with the respective lead frame attached to the die;
for each respective lead frame, forming a separate package casing over the die, the wire bonds, and the respective group of nickel-plated bond pads associated with the respective lead frame; and
subsequent to forming the separate package casing for each respective lead frame, separating the plurality of lead frames to form the plurality of lead frame packaged devices.

18. The method of claim 17, wherein depositing the tin plating on the lead frame array includes completely coating each of the plurality of leads with tin.

19. The method of claim 17, wherein the plating masking material is an organic solderability preservative (OSP), a photoresist material, a thermal resistance material, or a chemical resistance material.

20. A method of fabricating a lead frame packaged device, the method comprising:
providing a lead frame comprising at least one wire bond area and a plurality of leads extending from the at least one wire bond area, wherein each wire bond area includes a plurality of bond pads;
depositing a bonding layer on each wire bond area to form plated bond pads;
depositing a plating masking material on the nickel plating to form a masking layer on the bonding layer;
depositing a release layer on the lead frame, including on the plurality of leads;
removing the masking layer from the lead frame to expose the bonding layer on each wire bond area;
attaching a die to the lead frame;
forming wire bonds between the die and the plated bond pads; and
forming a package casing over the die, the wire bonds, and the nickel-plated bond pads.
